(19) United States
(12) Patent Application Publication
(10) Pub. No.: US 2026/0268958 A1
(43) Pub. Date: Sep. 10, 2026

(54) MEMORY SYSTEM PERFORMING SELF-REFRESH OPERATION

(71) Applicant: SK hynix Inc., Icheon-si Gyeonggi-do (KR)

(72) Inventors: Dong Ju YANG, Icheon-si Gyeonggi-do (KR); Tae Ho KIM, Icheon-si Gyeonggi-do (KR); Hyeon Jin YANG, Icheon-si Gyeonggi-do (KR); Se Jun HAN, Icheon-si Gyeonggi-do (KR)

(73) Assignee: SK hynix Inc., Icheon-si Gyeonggi-do (KR)

(21) Appl. No.: 19/242,601

(22) Filed: Jun. 18, 2025

(30) Foreign Application Priority Data
Mar. 6, 2025 (KR) 10-2025-0029342

(51) Int. Cl. G11C 11/406; G11C 11/4076

(52) U.S. Cl. CPC G11C 11/40626; G11C 11/40615; G11C 11/4076

(57) ABSTRACT

A memory device includes a base die configured to output a temperature code signal after the start of a self-refresh operation. The memory device also includes a core die. The core die is configured to generate a refresh code signal that is set as a gray code based on the temperature code signal. The core die is further configured to perform the self-refresh operation based on a refresh pulse signal having a generation cycle adjusted based on a combination of logic levels of the refresh code signal. The core die is additionally configured to adjust the generation cycle of the refresh pulse signal by latching the refresh code signal in synchronization with the refresh pulse signal.

### CROSS-REFERENCE TO RELATED APPLICATION

The present application claims priority under 35 U.S.C. § 119(a) to Korean Patent Application No. 10-2025-0029342, filed in the Korean Intellectual Property Office on Mar. 6, 2025, the entire contents of which application is incorporated herein by reference.

### BACKGROUND

The present disclosure relates to a memory system that adjusts the cycle of a self-refresh operation based on a refresh code signal that is a gray code.

A stack memory system, such as high bandwidth memory (HBM), is used in wide application fields due to its excellent bandwidth. Unlike the existing memory system using a parallel data bus, the stack memory system includes a stack memory device including a base die and core dies that are connected by through silicon vias (TSVs). The stack memory device includes a physical interface, such as a physical layer, for communication with a processor. The physical layer needs to be designed to guarantee high-speed data transmission and efficient communication.

Furthermore, the stack memory device is implemented by vertically stacking a plurality of core dies over a base die through TSVs. Each of the plurality of core dies includes a plurality of cell arrays. Each of the plurality of cell arrays includes a plurality of cells. Charges of data stored in the plurality of cells may leak by lapse of time. To prevent the phenomenon in which the data of the plurality of cells are lost over time as described above, the stack memory device is implemented to perform a refresh operation. The refresh operation includes an auto-refresh operation that is performed by a command and a self-refresh operation that is internally periodically performed by lapse of time.

### SUMMARY

In an embodiment, a memory device may include a base die configured to output a temperature code signal after the start of a self-refresh operation. The memory device may also include a core die configured to generate a refresh code signal that is set as a gray code based on the temperature code signal, configured to perform the self-refresh operation based on a refresh pulse signal having a generation cycle adjusted based on a combination of logic levels of the refresh code signal, and configured to adjust the generation cycle of the refresh pulse signal by latching the refresh code signal in synchronization with the refresh pulse signal.

In an embodiment, a memory device may include a base die configured to output a temperature code signal after the start of a self-refresh operation. The memory device may also include a core die including first and second channels. The first channel may be configured to generate a first refresh code signal that is set as a gray code based on the temperature code signal, perform the self-refresh operation based on a first refresh pulse signal having a generation cycle adjusted based on a combination of logic levels of the first refresh code signal, and adjust the generation cycle of the first refresh pulse signal by latching the first refresh code signal in synchronization with the first refresh pulse signal. The second channel may be configured to generate a second refresh code signal that is set as a gray code based on the temperature code signal, perform the self-refresh operation based on a second refresh pulse signal having a generation cycle adjusted based on a combination of logic levels of the second refresh code signal, and adjust the generation cycle of the second refresh pulse signal by latching the second refresh code signal in synchronization with the second refresh pulse signal.

In an embodiment, a memory device may include a base die configured to output a temperature code signal after the start of a self-refresh operation. The memory device may also include a core die including first and second channels. The first channel may be configured to generate a refresh code signal that is set as a gray code based on the temperature code signal, perform the self-refresh operation based on a first refresh pulse signal having a generation cycle adjusted based on a combination of logic levels of the refresh code signal, and adjust the generation cycle of the first refresh pulse signal by latching the refresh code signal in synchronization with the first refresh pulse signal. The second channel may be configured to receive the refresh code signal from the first channel, perform the self-refresh operation based on a second refresh pulse signal having a generation cycle adjusted based on a combination of logic levels of the refresh code signal, and adjust the generation cycle of the second refresh pulse signal by latching the refresh code signal in synchronization with the second refresh pulse signal.

In an embodiment, a semiconductor device may include a memory circuit configured to perform a self-refresh operation based on a refresh pulse signal. The semiconductor device may also include a refresh control circuit configured to generate a refresh code signal based on a temperature code signal that is input from an external device, configured to generate the refresh pulse signal based on a combination of logic levels of the refresh code signal, and configured to adjust a generation cycle of the refresh pulse signal by latching the refresh code signal in synchronization with the refresh pulse signal.

### BRIEF DESCRIPTION OF THE DRAWINGS

FIG. 1 is a block diagram illustrating a construction of a memory system according to an embodiment of the present disclosure.

FIG. 2 is a block diagram illustrating a construction of a core die according to an embodiment of the present disclosure.

FIG. 3 is a block diagram illustrating a construction of a first memory circuit according to an embodiment of the present disclosure.

FIG. 4 is a block diagram illustrating a construction of a first refresh control circuit according to an embodiment of the present disclosure.

FIG. 5 is a block diagram illustrating a construction according to an example of a self-refresh control circuit according to another embodiment of the present disclosure.

FIG. 6 is a circuit diagram illustrating a construction according to an example of a synthesis signal generation circuit according to another embodiment of the present disclosure.

FIG. 7 is a diagram illustrating a construction according to an example of a refresh pulse signal generation circuit according to an embodiment of the present disclosure.

FIG. 8 is a table for describing an operation of initializing a refresh code signal after the start of a boot-up operation and an operation of generating a temperature selection signal after the start of a boot-up operation according to an embodiment of the present disclosure.

FIG. 9 is a table for describing an operation of generating the refresh code signal based on a combination of the logic levels of a temperature code signal that is generated based on a temperature interval according to an embodiment of the present disclosure.

FIG. 10 is a table for describing an operation of generating, by a temperature selection signal generation circuit, the temperature selection signal based on the refresh code signal after the start of a self-refresh operation according to an embodiment of the present disclosure.

FIG. 11 is a timing diagram for describing an operation of a first refresh control circuit according to an embodiment of the present disclosure.

FIG. 12 is a block diagram illustrating a construction of a core die according to another embodiment of the present disclosure.

FIG. 13 is a block diagram illustrating a construction of a second refresh control circuit according to another embodiment of the present disclosure.

FIG. 14 is a diagram for describing an operation of a memory device according to an embodiment of the present disclosure.

### DETAILED DESCRIPTION

In the following detailed description, terms such as “first” and “second,” which are used to distinguish among various components, and not to imply a number or order of components, are not limited by the components. For example, a first component may be referred to as a second component, and vice versa.

When one component is referred to as being “coupled” or “connected” to another component, the components may be directly coupled or connected to each other, or they may be coupled or connected to each other through another component interposed therebetween. In contrast, when one component is referred to as being “directly coupled” or “directly connected” to another component, the components are directly coupled or connected to each other without another component interposed therebetween.

A “logic high level” and a “logic low level” are used to describe the logic levels of signals. A signal having a “logic high level” is distinguished from a signal having a “logic low level.” For example, when a signal having a first voltage corresponds to a signal having a “logic high level,” a signal having a second voltage different from the first voltage may correspond to a signal having a “logic low level.” According to an embodiment, a “logic high level” may indicate a voltage higher than a “logic low level.” According to an embodiment, the logic levels of signals may be different logic levels or opposite logic levels. For example, a signal having a logic high level may be set to have a logic low level in some embodiments, and a signal having a logic low level may be set to have a logic high level in some embodiments.

A “binary bit set” may refer a combination of logic levels of bits included in a signal. When a logic level of each of the bits included in the signal is changed, a binary bit set of the signal may be changed. For example, when the logic level of each of two bits included in a signal is a “logic low level, logic low level” when the two bits are included in the signal, a binary bit set of the signal may be indicated as “00.” When the logic level of each of the two bits included in the signal is a “logic low level, logic high level”, a binary bit set of the signal may be indicated as “01.”

Hereafter, the present disclosure will be described in more detail through referring to embodiments. The embodiments are only used to exemplify the present disclosure, and the scope of the present disclosure is not limited by the embodiments.

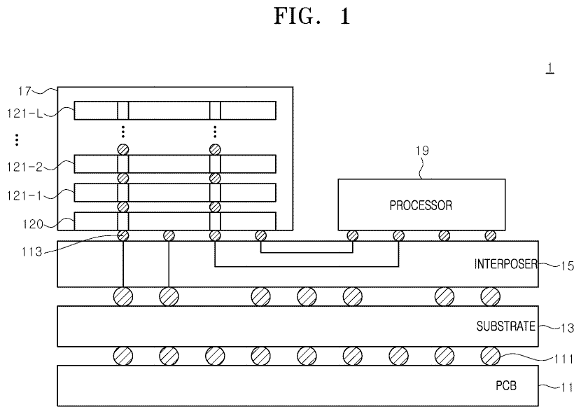

FIG. 1 is a block diagram illustrating a construction of a memory system 1 according to an embodiment of the present disclosure.

As illustrated in FIG. 1, the memory system 1 may include a printed circuit board (PCB) 11, a substrate 13, an interposer 15, a memory device 17, and a processor 19.

The PCB 11 connects several electronic parts to form an electronic circuit (not illustrated). A copper layer, a solder mask, and a silkscreen may be formed in the PCB 11. A circuit path along which a signal or power is transmitted may be formed in the copper layer. The solder mask prevents damage to the circuit and protects a specific region in which a part may be soldered. Furthermore, the silkscreen displays the locations of electronic parts or information in the form of letters or symbols printed on a surface of the PCB 11.

The substrate 13 is formed over the PCB 11 with bump pads 111 between the PCB 11 and the substrate 13. The substrate 13 may mechanically support the interposer 15, the memory device 17, and the processor 19. The substrate 13 may represent an insulating material. Materials of the substrate 13 include FR4 that is an insulator made of glass fiber and epoxy resin, ceramic that is mainly used in a high frequency circuit or a high temperature environment because the ceramic can withstand a high temperature and has excellent thermal conductivity, and polyimide that is used as a basic material of a flexible PCB due to a flexible characteristic.

The interposer 15 is formed over the substrate 13 with bump pads between them. The interposer 15 may include electronic parts having form factors or pin arrangements not matched, for example, wires that connect the memory device 17 and the processor 19. The interposer 15 may convert signals at different interfaces.

The memory device 17 may be formed over the interposer 15 with micro bump pads 113 between the interposer 15 and the memory device 17. The memory device 17 may store data output by the processor 19 or may output stored data to the processor 19 under the control of the processor 19.

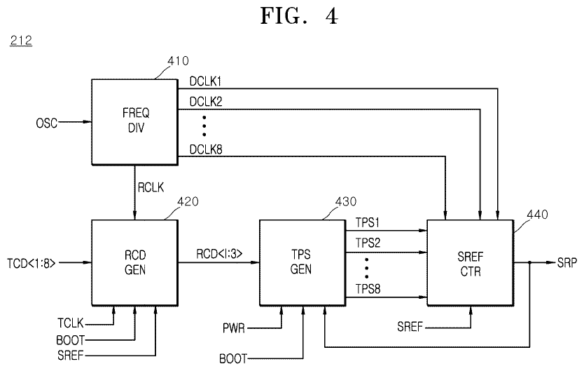

The memory device 17 may include a base die 120 and a plurality of core dies 121-1 to 121-L. The base die 120 may be stacked over the interposer 15 on the micro bump pads 113. The base die 120 may control operations of the plurality of core dies 121-1 to 121-L. The base die 120 may output a temperature code signal TCD<1:8> (shown in FIG. 4) to the plurality of core dies 121-1 to 121-L after the start of a self-refresh operation. The plurality of core dies 121-1 to 121-L may be stacked over the base die 120 and separated by micro bump pads. The base die 120 and the plurality of core dies 121-1 to 121-L may be vertically connected through through silicon vias (TSVs). The plurality of core dies 121-1 to 121-L may generate a refresh code signal RCD<1:3> (shown in FIG. 4) that is set as a gray code based on the temperature code signal TCD<1:8> after the start of a self-refresh operation. In accordance with an embodiment, a gray code is a binary numeral system where two successive values differ in only one bit position. The plurality of core dies 121-1 to 121-L may generate a refresh pulse signal SRP (shown in FIG. 4) having a generation cycle adjusted based on a combination of the logic levels of the refresh code signal RCD<1:3>. The plurality of core dies 121-1 to 121-L may perform a self-refresh operation based on the refresh pulse signal SRP. The plurality of core dies 121-1 to 121-L may adjust the generation cycle of the refresh pulse signal SRP by latching the refresh code signal RCD<1:3> in synchronization with the refresh pulse signal SRP. Each of the plurality of core dies 121-1 to 121-L may include a plurality of channel regions that operate independently. Each of the plurality of channel regions may be assigned a channel that operates independently and may receive or transmit data. Each of the plurality of channel regions may perform a self-refresh operation based on the refresh pulse signal SRP. The base die 120 may be identified by a name, such as a base chip, a semiconductor chip, or a semiconductor device. The core dies 121-1 to 121-L may be identified by a name, such as a core chip, a semiconductor chip, or a semiconductor device.

The number L of the plurality of core dies 121-1 to 121-L may be 4, 8, 12, or 16. For example, when each of the core dies 121-1 to 121-12 has eight channels, each of the core dies 121-1 to 121-4, the core dies 121-5 to 121-8, and the core dies 121-9 to 121-12 includes 32 channel regions and may transmit and receive data to and from the processor 19 in a rank unit including thirty-second channels.

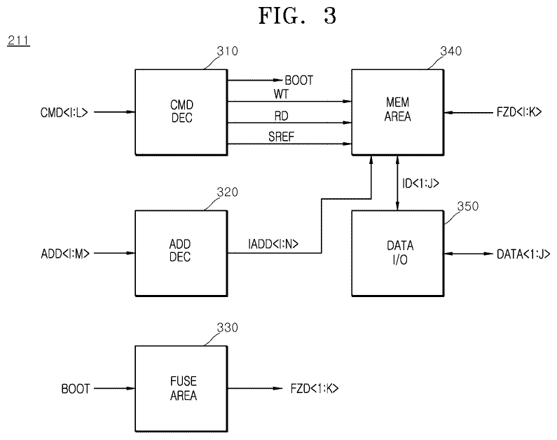

The processor 19 may control the base die 120 that outputs a command CMD<1:L> (shown in FIG. 3) and an address ADD<1:M> (shown in FIG. 3) to the core dies 121-1 to 121-L through the wires formed within the interposer 15.

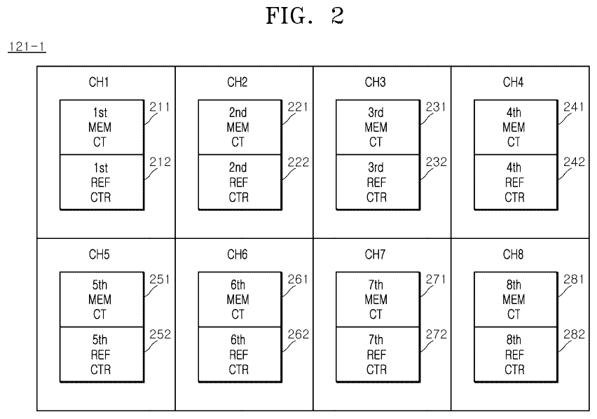

FIG. 2 is a block diagram illustrating a construction of the first core die 121-1, among the plurality of core dies 121-1 to 121-L, according to an embodiment of the present disclosure. As illustrated in FIG. 2, the first core die 121-1 may include a first channel CH1, a second channel CH2, a third channel CH3, a fourth channel CH4, a fifth channel CH5, a sixth channel CH6, a seventh channel CH7, and an eighth channel CH8.

The first channel CH1 may include a first memory circuit (1^{st} MEM CT) 211 and a first refresh control circuit (1^{st} REF CTR) 212.

The first memory circuit 211 may perform a boot-up operation, a write operation, a read operation, and a self-refresh operation based on the command CMD<1:L> (shown in FIG. 3) and the address ADD<1: M> (shown in FIG. 3). The first memory circuit 211 may perform various operations based on the command CMD<1:L> and the address ADD<1:M>. The first memory circuit 211 may output the fuse data FZD<1:K> (shown in FIG. 3) programmed in a fuse area FUSE AREA 330 (shown in FIG. 3) after the start of a boot-up operation based on the command CMD<1:L> and the address ADD<1:M>. The first memory circuit 211 may store data DATA<1:J> (shown in FIG. 3) in a memory area MEM AREA 340 (shown in FIG. 3) after the start of a write operation based on the command CMD<1:L> and the address ADD<1:M>. The first memory circuit 211 may output the data DATA<1:J> stored in the memory area 340 after the start of a read operation based on the command CMD<1:L> and the address ADD<1:M>. The first memory circuit 211 may perform a self-refresh operation by the refresh pulse signal SRP (shown in FIG. 4) after the start of a self-refresh operation based on the command CMD<1:L>.

The first refresh control circuit 212 may generate the refresh code signal RCD<1:3> (shown in FIG. 4) that is set as a gray code, based on the temperature code signal TCD<1:8> (shown in FIG. 4). The first refresh control circuit 212 may generate the refresh pulse signal SRP having a generation cycle adjusted based on a combination of the logic levels of the refresh code signal RCD<1:3>. The first refresh control circuit 212 may adjust the generation cycle of the refresh pulse signal SRP by latching the refresh code signal RCD<1:3> in synchronization with the refresh pulse signal SRP.

The second channel CH2 may include a second memory circuit (2^{nd} MEM CTR) 221 and a second refresh control circuit (2^{nd} REF CTR) 222. The third channel CH3 may include a third memory circuit (3^{rd} MEM CTR) 231 and a third refresh control circuit (3^{rd} REF CTR) 232. The fourth channel CH4 may include a fourth memory circuit (4^{th} MEM CTR) 241 and a fourth refresh control circuit (4^{th} REF CTR) 242. The fifth channel CH5 may include a fifth memory circuit (5^{th} MEM CTR) 251 and a fifth refresh control circuit (5^{th} REF CTR) 252. The sixth channel CH6 may include a sixth memory circuit (6^{th} MEM CTR) 261 and a sixth refresh control circuit (6^{th} REF CTR) 262. The seventh channel CH7 may include a seventh memory circuit (7^{th} MEM CTR) 271 and a seventh refresh control circuit (7^{th} REF CTR) 272. The eighth channel CH8 may include an eighth memory circuit (8^{th} MEM CTR) 281 and an eighth refresh control circuit (8^{th} REF CTR) 282.

Each of the second to eighth channels CH2 to CH8 includes the same components as the first channel CH1 and performs the same operation as the first channel CH1, and thus, a detailed description thereof is not repeated.

FIG. 3 is a block diagram illustrating a construction of the first memory circuit 211, according to an embodiment of the present disclosure. As illustrated in FIG. 3, the first memory circuit 211 may include a command decoder (CMD DEC) 310, an address decoder (ADD DEC) 320, the fuse area (FUSE AREA) 330, the memory area (MEM AREA) 340, and a data input and output circuit (DATA I/O) 350.

The command decoder 310 may generate a boot-up signal BOOT, a write signal WT, a read signal RD, and a self-refresh signal SREF based on the first to L-th bits CMD<1:L> of the command. The command decoder 310 may generate the boot-up signal BOOT, the write signal WT, the read signal RD, and the self-refresh signal SREF that are selectively enabled by decoding the first to L-th bits CMD<1:L> of the command. The command decoder 310 may generate the boot-up signal BOOT that is enabled when the first to L-th bits CMD<1:L> of the command have a combination of logic levels for the performance of a boot-up operation. The command decoder 310 may generate the write signal WT that is enabled when the first to L-th bits CMD<1:L> of the command have a combination of logic levels for the performance of a write operation. The command decoder 310 may generate the read signal RD that is enabled when the first to L-th bits CMD<1:L> of the command have a combination of logic levels for the performance of a read operation. The command decoder 310 may generate the self-refresh signal SREF that is enabled when the first to L-th bits CMD<1:L> of the command have a combination of logic levels for the performance of a self-refresh operation. The command has been set to include the L bits, but may be set to include various numbers of bits according to different embodiments. The number L of first to L-th bits CMD<1:L> of the command may be an integer greater than 0. The first to L-th bits CMD<1:L> of the command may be a command signal that controls operations of the plurality of core dies 121-1 to 121-L.

The boot-up operation may be an operation of outputting information programmed in the fuse area 330. The write operation may be an operation of storing, in the memory area 340, the first to J-th bits ID<1:J> of internal data that are generated from the first to J-th bits DATA<1:J> of the data. The read operation may be an operation of outputting the first to J-th bits DATA<1:J> of the data that are generated from the first to J-th bits ID<1:J> of the internal data stored in the memory area 340. The self-refresh operation may be a refresh operation of storing the first to J-th bits ID<1:J> of the internal data stored in a memory cell (not illustrated) again by periodically sensing and amplifying the first to J-th bits ID<1:J> of the internal data. The self-refresh operation may be an operation of storing data stored in a memory cell again by sensing and amplifying the data within a retention time during which the data are not lost.

The address decoder 320 may generate the first to N-th bits IADD<1:N> of internal address based on the first to M-th bits ADD<1:M> of the address. The address decoder 320 may generate the first to N-th bits IADD<1:N> of the internal address that are selectively enabled by decoding the first to M-th bits ADD<1:M> of the address. The address has been set to include the M bits, but may be set to include various numbers of bits according to different embodiments. The number M of first to M-th bits ADD<1:M> of the address may be an integer greater than 0. The first to M-th bits ADD<1:M> of the address may be an address signal that selects a plurality of memory cells included in the memory area 340. The internal address has been set to include the N bits, but may be set to include various numbers of bits according to different embodiments. The number N of first to N-th bits IADD<1:N> of the internal address may be an integer greater than 0.

The fuse area 330 may be implemented with a fuse circuit including a plurality of fuses. The plurality of fuses included in the fuse area 330 may be implemented with an E-fuse that is electrically programmed as the material of the E-fuse is ruptured when a high current is applied to the E-fuse. The fuse area 330 may output the first to K-th bits FZD<1:K> of fuse data that have been programmed when the boot-up signal BOOT is enabled. The first to K-th bits FZD<1:K> of the fuse data may be a signal including location information of a memory cell in which a failure occurs, among memory cells (not illustrated) included in the memory area 340. The first to K-th bits FZD<1:K> of the fuse data may be a signal including various types of information according to an embodiment. The number K of first to K-th bits FZD<1:K> of the fuse data may be an integer greater than 0.

The memory area 340 may be implemented with a memory circuit including a plurality of memory cells (not illustrated). The memory area 340 may store the first to J-th bits ID<1:J> of the internal data in a memory cell that is selected by the first to N-th bits IADD<1:N> of the internal address when the write signal WT is enabled. The memory area 340 may output the first to J-th bits ID<1:J> of the internal data stored in a memory cell that is selected by the first to N-th bits IADD<1:N> of the internal address when the read signal RD is enabled. The memory area 340 may store the first to J-th bits ID<1:J> of the internal data stored in a memory cell, which is selected by the first to N-th bits IADD<1:N> of the internal address that are sequentially counted when the self-refresh signal SREF is enabled, again by sensing and amplifying the first to J-th bits ID<1:J> of the internal data. The memory area 340 may perform a repair operation when the first to N-th bits IADD<1:N> of the internal address have a combination of logic levels that selects a memory cell in which a failure occurs, by comparing the first to N-th bits IADD<1:N> of the internal address and the first to K-th bits FZD<1:K> of the fuse data after the start of a write operation and a read operation. The repair operation refers to an operation of performing a write operation and a read operation by replacing a memory cell in which a failure occurs with a redundancy cell (not illustrated). The internal data has been set to include the J bits, but may be set to include various numbers of bits according to different embodiments. The number J of first to J-th bits ID<1:J> of the internal data may be an integer greater than 0.

The data input and output circuit 350 may receive the first to J-th bits DATA<1:J> of the data from the base die 120 after the start of a write operation. The data input and output circuit 350 may generate the first to J-th bits ID<1:J> of the internal data from the first to J-th bits DATA<1:J> of the data after the start of a write operation. The data input and output circuit 350 may output the first to J-th bits ID<1:J> of the internal data to the memory area 340 after the start of a write operation. The data input and output circuit 350 may receive the first to J-th bits ID<1:J> of the internal data from the memory area 340 after the start of a read operation. The data input and output circuit 350 may generate the first to J-th bits DATA<1:J> of the data from the first to J-th bits ID<1:J> of the internal data after the start of a read operation. The data input and output circuit 350 may output the first to J-th bits DATA<1:J> of the data to the base die 120 after the start of a read operation. The data has been set to include the J bits, but may be set to include various numbers of bits according to different embodiments. The number J of first to J-th bits DATA<1:J> of the data may be an integer greater than 0.

FIG. 4 is a block diagram illustrating a construction of the first refresh control circuit 212 according to an embodiment of the present disclosure. As illustrated in FIG. 4, the first refresh control circuit 212 may include a frequency division circuit (FREQ DIV) 410, a refresh code signal generation circuit (RCD GEN) 420, a temperature selection signal generation circuit (TPS GEN) 430, and a self-refresh control circuit (SREF CTR) 440.

The frequency division circuit 410 may generate a refresh clock signal RCLK based on a cycle signal OSC. The frequency division circuit 410 may generate the refresh clock signal RCLK having the same generation cycle as the cycle signal OSC. The cycle signal OSC may be a signal including a pulse that is periodically generated.

The frequency division circuit 410 may generate first to eighth division clock signals DCLK1 to DCLK8 based on the cycle signal OSC. The frequency division circuit 410 may generate the first to eighth division clock signals DCLK1 to DCLK8 having generation cycles sequentially increased by dividing the frequency of the cycle signal OSC. The frequency division circuit 410 may generate the first division clock signal DCLK1 having the same generation cycle as the cycle signal OSC. The frequency division circuit 410 may generate the second division clock signal DCLK2 having a generation cycle that is twice the generation cycle of the cycle signal OSC. The frequency division circuit 410 may generate the third division clock signal DCLK3 having a generation cycle that is three times the generation cycle of the cycle signal OSC. The frequency division circuit 410 may generate the fourth division clock signal DCLK4 having a generation cycle that is four times the generation cycle of the cycle signal OSC. The frequency division circuit 410 may generate the fifth division clock signal DCLK5 having a generation cycle that is five times the generation cycle of the cycle signal OSC. The frequency division circuit 410 may generate the sixth division clock signal DCLK6 having a generation cycle that is six times the generation cycle of the cycle signal OSC. The frequency division circuit 410 may generate the seventh division clock signal DCLK7 having a generation cycle that is seven times the generation cycle of the cycle signal OSC. The frequency division circuit 410 may generate the eighth division clock signal DCLK8 having a generation cycle that is eight times the generation cycle of the cycle signal OSC. An operation of generating, by the frequency division circuit 410, the second division clock signal DCLK2 having a generation cycle that is twice the generation cycle of the cycle signal OSC may be an operation of generating the second division clock signal DCLK2 including a pulse that is generated in a frequency that is half the frequency of a generation cycle of a pulse included in the cycle signal OSC.

Each of the first to eighth division clock signals DCLK1 to DCLK8 may be generated to have a different generation cycle. The first division clock signal DCLK1 may be generated including a pulse having a cycle of 0.5 μs, that is, a first cycle. The second division clock signal DCLK2 may be generated including a pulse having a cycle of 1 μs, that is, a second cycle. The third division clock signal DCLK3 may be generated including a pulse having a cycle of 2 μs, that is, a third cycle. The fourth division clock signal DCLK4 may be generated including a pulse having a cycle of 4 μs, that is, a fourth cycle. The fifth division clock signal DCLK5 may be generated including a pulse having a cycle of 8 μs, that is, a fifth cycle. The sixth division clock signal DCLK6 may be generated including a pulse having a cycle of 16 μs, that is, a sixth cycle. The seventh division clock signal DCLK7 may be generated including a pulse having a cycle of 32 μs, that is, a seventh cycle. The eighth division clock signal DCLK8 may be generated including a pulse having a cycle of 64 μs, that is, an eighth cycle. The abbreviation “μs” for microsecond indicates 10⁻⁶ second.

The refresh code signal generation circuit 420 may generate the first to third bits RCD<1:3> of the refresh code signal, which are initialized as a combination of logic levels corresponding to a high temperature when the boot-up signal BOOT is enabled. The first to third bits RCD<1:3> of the refresh code signal, which are initialized as a combination of logic levels corresponding to a high temperature in the refresh code signal generation circuit 420, may be set so the first bit RCD<1> of the refresh code signal is at a logic low level (L), the second bit RCD<2> of the refresh code signal is at a logic low level (L), and the third bit RCD<3> of the refresh code signal is generated at a logic high level (H). The first to third bits RCD<1:3> of the refresh code signal, which are initialized as a combination of logic levels corresponding to a high temperature in the refresh code signal generation circuit 420, may be variously set according to different embodiments.

The refresh code signal generation circuit 420 may receive the first to eighth bits TCD<1:8> of the temperature code signal in synchronization with a temperature clock signal TCLK during an interval for which the self-refresh signal SREF is enabled. The refresh code signal generation circuit 420 may generate the first to third bits RCD<1:3> of the refresh code signal based on a combination of the logic levels of the first to eighth bits TCD<1:8> of the temperature code signal in synchronization with the refresh clock signal RCLK during the interval for which the self-refresh signal SREF is enabled. The first to third bits RCD<1:3> of the refresh code signal may be set as a gray code. The first to third bits RCD<1:3> of the refresh code signal may be generated so that any one logic level, among the first to third bits RCD<1:3> of the refresh code signal, is changed when a combination of the logic levels of the first to eighth bits TCD<1:8> of the temperature code signal is changed. For an embodiment, only one logic level is changed, consistent with a gray code.

The temperature selection signal generation circuit 430 may generate first to eighth temperature selection signals TPS1 to TPS8 all of which are disabled when a power-up signal PWR is enabled. The temperature selection signal generation circuit 430 may generate the first temperature selection signal TPS1 that is enabled based on the first to third bits RCD<1:3> of the refresh code signal, which are set as a combination of logic levels corresponding to a high temperature, when the boot-up signal BOOT is enabled. The temperature selection signal generation circuit 430 may generate the first to eighth temperature selection signals TPS1 to TPS8 based on the first to third bits RCD<1:3> of the refresh code signal in synchronization with the refresh pulse signal SRP. The temperature selection signal generation circuit 430 may generate the first to eighth temperature selection signals TPS1 to TPS8 that are selectively enabled by decoding the first to third bits RCD<1:3> of the refresh code signal when the level of the refresh pulse signal SRP transitions to a logic low level.

The self-refresh control circuit 440 may generate the refresh pulse signal SRP having a generation cycle adjusted, based on the first to eighth temperature selection signals TPS1 to TPS8 and the first to eighth division clock signals DCLK1 to DCLK8 during the interval for which the self-refresh signal SREF is enabled. The self-refresh control circuit 440 may generate the refresh pulse signal SRP from the first division clock signal DCLK1 when the first temperature selection signal TPS1 is enabled during the interval for which the self-refresh signal SREF is enabled. The self-refresh control circuit 440 may generate the refresh pulse signal SRP from the second division clock signal DCLK2 when the second temperature selection signal TPS2 is enabled during the interval for which the self-refresh signal SREF is enabled. The self-refresh control circuit 440 may generate the refresh pulse signal SRP from the third division clock signal DCLK3 when the third temperature selection signal TPS3 is enabled during the interval for which the self-refresh signal SREF is enabled. The self-refresh control circuit 440 may generate the refresh pulse signal SRP from the fourth division clock signal DCLK4 when the fourth temperature selection signal TPS4 is enabled during the interval for which the self-refresh signal SREF is enabled. The self-refresh control circuit 440 may generate the refresh pulse signal SRP from the fifth division clock signal DCLK5 when the fifth temperature selection signal TPS5 is enabled during the interval for which the self-refresh signal SREF is enabled. The self-refresh control circuit 440 may generate the refresh pulse signal SRP from the sixth division clock signal DCLK6 when the sixth temperature selection signal TPS6 is enabled during the interval for which the self-refresh signal SREF is enabled. The self-refresh control circuit 440 may generate the refresh pulse signal SRP from the seventh division clock signal DCLK7 when the seventh temperature selection signal TPS7 is enabled during the interval for which the self-refresh signal SREF is enabled. The self-refresh control circuit 440 may generate the refresh pulse signal SRP from the eighth division clock signal DCLK8 when the eighth temperature selection signal TPS8 is enabled during the interval for which the self-refresh signal SREF is enabled.

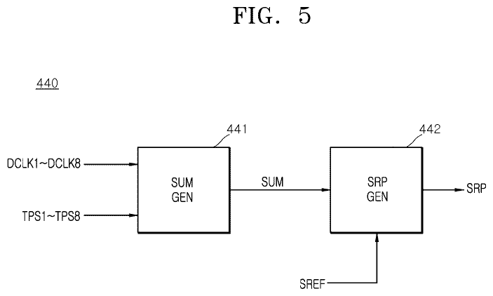

FIG. 5 is a block diagram illustrating a construction according to an example of the self-refresh control circuit 440 according to another embodiment of the present disclosure. As illustrated in FIG. 5, the self-refresh control circuit 440 may include a synthesis signal generation circuit (SUM GEN) 441 and a refresh pulse signal generation circuit (SRP GEN) 442.

The synthesis signal generation circuit 441 may generate a synthesis signal SUM by synthesizing the first to eighth temperature selection signals TPS1 to TPS8 and the first to eighth division clock signals DCLK1 to DCLK8. The synthesis signal generation circuit 441 may generate the synthesis signal SUM from the first division clock signal DCLK1 when the first temperature selection signal TPS1 is enabled. The synthesis signal generation circuit 441 may generate the synthesis signal SUM from the second division clock signal DCLK2 when the second temperature selection signal TPS2 is enabled. The synthesis signal generation circuit 441 may generate the synthesis signal SUM from the third division clock signal DCLK3 when the third temperature selection signal TPS3 is enabled. The synthesis signal generation circuit 441 may generate the synthesis signal SUM from the fourth division clock signal DCLK4 when the fourth temperature selection signal TPS4 is enabled. The synthesis signal generation circuit 441 may generate the synthesis signal SUM from the fifth division clock signal DCLK5 when the fifth temperature selection signal TPS5 is enabled. The synthesis signal generation circuit 441 may generate the synthesis signal SUM from the sixth division clock signal DCLK6 when the sixth temperature selection signal TPS6 is enabled. The synthesis signal generation circuit 441 may generate the synthesis signal SUM from the seventh division clock signal DCLK7 when the seventh temperature selection signal TPS7 is enabled. The synthesis signal generation circuit 441 may generate the synthesis signal SUM from the eighth division clock signal DCLK8 when the eighth temperature selection signal TPS8 is enabled.

The refresh pulse signal generation circuit 442 may generate the refresh pulse signal SRP based on the synthesis signal SUM during the interval for which the self-refresh signal SREF is enabled. The refresh pulse signal generation circuit 442 may generate the refresh pulse signal SRP by delaying the synthesis signal SUM during the interval for which the self-refresh signal SREF is enabled.

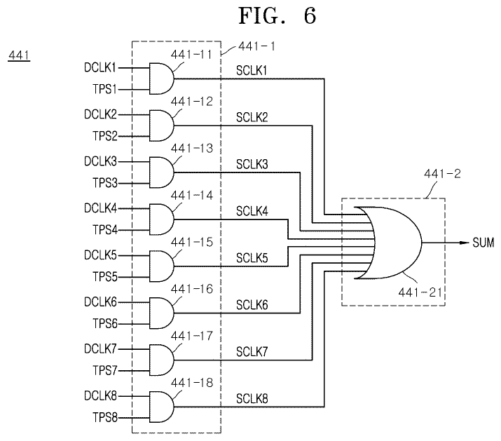

FIG. 6 is a circuit diagram illustrating a construction according to an example of the synthesis signal generation circuit 441 according to another embodiment of the present disclosure. As illustrated in FIG. 6, the synthesis signal generation circuit 441 may include a selection clock signal generation circuit 441-1 and a first logic circuit 441-2.

The selection clock signal generation circuit 441-1 may be implemented with first to eighth AND gates 441-11 to 441-18.

The first AND gate 441-11 may generate a first selection clock signal SCLK1 by performing an AND operation on the first temperature selection signal TPS1 and the first division clock signal DCLK1. The first AND gate 441-11 may generate the first selection clock signal SCLK1 by buffering the first division clock signal DCLK1 when the first temperature selection signal TPS1 is enabled to a logic high level.

The second AND gate 441-12 may generate a second selection clock signal SCLK2 by performing an AND operation on the second temperature selection signal TPS2 and the second division clock signal DCLK2. The second AND gate 441-12 may generate the second selection clock signal SCLK2 by buffering the second division clock signal DCLK2 when the second temperature selection signal TPS2 is enabled to a logic high level.

The third AND gate 441-13 may generate a third selection clock signal SCLK3 by performing an AND operation on the third temperature selection signal TPS3 and the third division clock signal DCLK3. The third AND gate 441-13 may generate the third selection clock signal SCLK3 by buffering the third division clock signal DCLK3 when the third temperature selection signal TPS3 is enabled to a logic high level.

The fourth AND gate 441-14 may generate a fourth selection clock signal SCLK4 by performing an AND operation on the fourth temperature selection signal TPS4 and the fourth division clock signal DCLK4. The fourth AND gate 441-14 may generate the fourth selection clock signal SCLK4 by buffering the fourth division clock signal DCLK4 when the fourth temperature selection signal TPS4 is enabled to a logic high level.

The fifth AND gate 441-15 may generate a fifth selection clock signal SCLK5 by performing an AND operation on the fifth temperature selection signal TPS5 and the fifth division clock signal DCLK5. The fifth AND gate 441-15 may generate the fifth selection clock signal SCLK5 by buffering the fifth division clock signal DCLK5 when the fifth temperature selection signal TPS5 is enabled to a logic high level.

The sixth AND gate 441-16 may generate a sixth selection clock signal SCLK6 by performing an AND operation on the sixth temperature selection signal TPS6 and the sixth division clock signal DCLK6. The sixth AND gate 441-16 may generate the sixth selection clock signal SCLK6 by buffering the sixth division clock signal DCLK6 when the sixth temperature selection signal TPS6 is enabled to a logic high level.

The seventh AND gate 441-17 may generate a seventh selection clock signal SCLK7 by performing an AND operation on the seventh temperature selection signal TPS7 and the seventh division clock signal DCLK7. The seventh AND gate 441-17 may generate the seventh selection clock signal SCLK7 by buffering the seventh division clock signal DCLK7 when the seventh temperature selection signal TPS7 is enabled to a logic high level.

The eighth AND gate 441-18 may generate an eighth selection clock signal SCLK8 by performing an AND operation on the eighth temperature selection signal TPS8 and the eighth division clock signal DCLK8. The eighth AND gate 441-18 may generate the eighth selection clock signal SCLK8 by buffering the eighth division clock signal DCLK8 when the eighth temperature selection signal TPS8 is enabled to a logic high level.

The selection clock signal generation circuit 441-1 may output one of the first to eighth division clock signals DCLK1 to DCLK8 corresponding to a signal that is enabled, among the first to eighth temperature selection signals TPS1 to TPS8, as one of the first to eighth selection clock signals SCLK1 to SCLK8.

The first logic circuit 441-2 may be implemented with an OR gate 441-21.

The OR gate 441-21 may generate the synthesis signal SUM by performing an OR operation on the first to eighth selection clock signals SCLK1 to SCLK8. The OR gate 441-21 may generate the synthesis signal SUM that is enabled to a logic high level when any one of the first to eighth selection clock signals SCLK1 to SCLK8 is generated at a logic high level.

The first logic circuit 441-2 may generate the synthesis signal SUM by synthesizing the first to eighth selection clock signals SCLK1 to SCLK8.

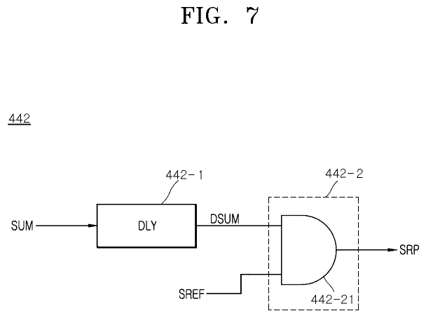

FIG. 7 is a diagram illustrating a construction according to an example of the refresh pulse signal generation circuit 442 according to an embodiment of the present disclosure. As illustrated in FIG. 7, the refresh pulse signal generation circuit 442 may include a delay circuit (DLY) 442-1 and a second logic circuit 442-2.

The delay circuit 442-1 may generate a delayed synthesis signal DSUM by delaying the synthesis signal SUM. The delay circuit 442-1 is implemented with a common delay circuit, and may generate the delayed synthesis signal DSUM by delaying the synthesis signal SUM. The delay time of the delay circuit 442-1 may be variously set according to different embodiments.

The second logic circuit 442-2 may be implemented with an AND gate 442-21.

The AND gate 442-21 may generate the refresh pulse signal SRP by performing an AND operation on the delayed synthesis signal DSUM and the self-refresh signal SREF. The AND gate 442-21 may generate the refresh pulse signal SRP by buffering the delayed synthesis signal DSUM during the interval for which the self-refresh signal SREF is enabled to a logic high level.

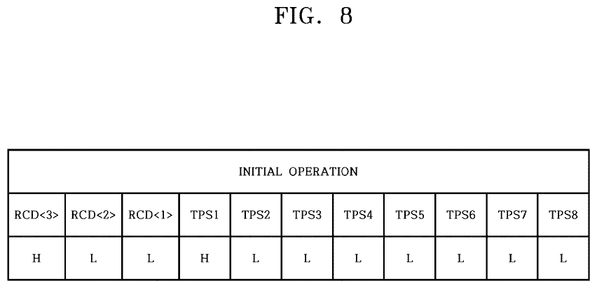

FIG. 8 is a table for describing an operation of initializing (INITIAL OPERATION) the refresh code signal after the start of a boot-up operation and an operation of generating the temperature selection signal after the start of a boot-up operation according to an embodiment of the present disclosure.

The refresh code signal generation circuit 420 generates the first to third bits RCD<1:3> (“H, L, L”) of the refresh code signal, which are initialized as a combination of logic levels corresponding to a high temperature when the boot-up signal BOOT is enabled.

The refresh code signal generation circuit 420 generates the first bit RCD<1> of the refresh code signal, which is at a logic low level (L), generates the second bit RCD<2> of the refresh code signal, which is at a logic low level (L), and generates the third bit RCD<3> of the refresh code signal, which is at a logic high level (H), when the boot-up signal BOOT is enabled.

The temperature selection signal generation circuit 430 generates the first to eighth temperature selection signals TPS1 to TPS8 based on the first to third bits RCD<1:3> (“H, L, L”) of the refresh code signal, which are initialized when the boot-up signal BOOT is enabled.

The temperature selection signal generation circuit 430 generates the first temperature selection signal TPS1 at a logic high level (H) by decoding the first to third bits RCD<1:3> (“H, L, L”) of the refresh code signal, which are initialized when the boot-up signal BOOT is enabled, and generates the second to eighth temperature selection signals TPS2 to TPS8 at a logic low level (L).

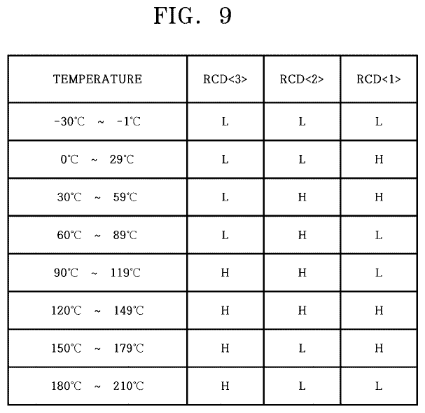

FIG. 9 is a table for describing an operation of generating the refresh code signal RCD<1:3> based on a combination of the logic levels of the temperature code signal TCD<1:8> that is generated based on a temperature interval according to an embodiment of the present disclosure.

Prior to a description, a combination of the logic levels of the first to eighth bits TCD<1:8> of the temperature code signal may be variously set for each temperature interval according to an embodiment. A combination of the logic levels of the first to eighth bits TCD<1:8> of the temperature code signal may be identically generated for each temperature interval. Furthermore, when the temperature interval is changed, a combination of the logic levels of the first to eighth bits TCD<1:8> of the temperature code signal may be changed.

The refresh code signal generation circuit 420 generates the first bit RCD<1> of the refresh code signal, which is at a logic low level (L), generates the second bit RCD<2> of the refresh code signal, which is at a logic low level (L), and generates the third bit RCD<3> of the refresh code signal, which is at a logic low level (L), based on a combination of the logic levels of the first to eighth bits TCD<1:8> of the temperature code signal during an interval in which a temperature interval is −30° C. to −1° C.

The refresh code signal generation circuit 420 generates the first bit RCD<1> of the refresh code signal, which is at a logic high level (H), generates the second bit RCD<2> of the refresh code signal, which is at a logic low level (L), and generates the third bit RCD<3> of the refresh code signal, which is at a logic low level (L), based on a combination of the logic levels of the first to eighth bits TCD<1:8> of the temperature code signal during an interval in which a temperature interval is 0° C. to 29° C.

The refresh code signal generation circuit 420 generates the first bit RCD<1> of the refresh code signal, which is at a logic high level (H), generates the second bit RCD<2> of the refresh code signal, which is at a logic high level (H), and generates the third bit RCD<3> of the refresh code signal, which is at a logic low level (L), based on a combination of the logic levels of the first to eighth bits TCD<1:8> of the temperature code signal during an interval in which a temperature interval is 30° C. to 59° C.

The refresh code signal generation circuit 420 generates the first bit RCD<1> of the refresh code signal, which is at a logic low level (L), generates the second bit RCD<2> of the refresh code signal, which is at a logic high level (H), and generates the third bit RCD<3> of the refresh code signal, which is at a logic low level (L), based on a combination of the logic levels of the first to eighth bits TCD<1:8> of the temperature code signal during an interval in which a temperature interval is 60° C. to 89° C.

The refresh code signal generation circuit 420 generates the first bit RCD<1> of the refresh code signal, which is at a logic low level (L), generates the second bit RCD<2> of the refresh code signal, which is at a logic high level (H), and generates the third bit RCD<3> of the refresh code signal, which is at a logic high level (H), based on a combination of the logic levels of the first to eighth bits TCD<1:8> of the temperature code signal during an interval in which a temperature interval is 90° C. to 119° C.

The refresh code signal generation circuit 420 generates the first bit RCD<1> of the refresh code signal, which is at a logic high level (H), generates the second bit RCD<2> of the refresh code signal, which is at a logic high level (H), and generates the third bit RCD<3> of the refresh code signal, which is at a logic high level (H), based on a combination of the logic levels of the first to eighth bits TCD<1:8> of the temperature code signal during an interval in which a temperature interval is 120° C. to 149° C.

The refresh code signal generation circuit 420 generates the first bit RCD<1> of the refresh code signal, which is at a logic high level (H), generates the second bit RCD<2> of the refresh code signal, which is at a logic low level (L), and generates the third bit RCD<3> of the refresh code signal, which is at a logic high level (H), based on a combination of the logic levels of the first to eighth bits TCD<1:8> of the temperature code signal during an interval in which a temperature interval is 150° C. to 179° C.

The refresh code signal generation circuit 420 generates the first bit RCD<1> of the refresh code signal, which is at a logic low level (L), generates the second bit RCD<2> of the refresh code signal, which is at a logic low level (L), and generates the third bit RCD<3> of the refresh code signal, which is at a logic high level (H), based on a combination of the logic levels of the first to eighth bits TCD<1:8> of the temperature code signal during an interval in which a temperature interval is 180° C. to 210° C.

The interval in which the temperature interval is 180° C. to 210° C. may be set as a temperature interval for which the first to third bits RCD<1:3> of the refresh code signal, which are initialized as a combination of logic levels corresponding to a high temperature, are generated after the start of a boot-up operation.

As described above, according to an embodiment, the logic level of one of the first to third bits RCD<1:3> of the refresh code signal may be changed when a combination of the logic levels of the first to eighth bits TCD<1:8> of the temperature code signal is changed. That is, the first to third bits RCD<1:3> of the refresh code signal may be set as a gray code.

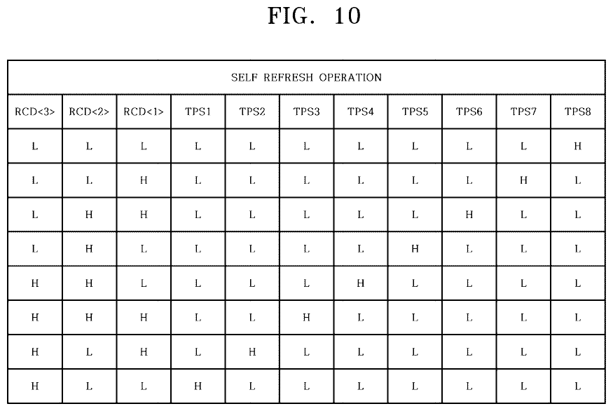

FIG. 10 is a table for describing an operation of generating, by the temperature selection signal generation circuit 430, the temperature selection signals TPS1 to TPS8 based on the refresh code signal RCD<1:3> after the start of a self-refresh operation according to an embodiment of the present disclosure.

The temperature selection signal generation circuit 430 generates the eighth temperature selection signal TPS8 enabled to a logic high level (H), with remaining temperature selection signals TPS1 to TPS7 disabled to a logic low level (L), when the first bit RCD<1> of the refresh code signal is at a logic low level (L), the second bit RCD<2> of the refresh code signal is at a logic low level (L), and the third bit RCD<3> of the refresh code signal is at a logic low level (L) in synchronization with the refresh pulse signal SRP.

The temperature selection signal generation circuit 430 generates the seventh temperature selection signal TPS7 enabled to a logic high level (H), with remaining temperature selection signals TPS1 to TPS6 and TPS8 disabled to a logic low level (L), when the first bit RCD<1> of the refresh code signal is at a logic high level (H), the second bit RCD<2> of the refresh code signal is at a logic low level (L), and the third bit RCD<3> of the refresh code signal is at a logic low level (L) in synchronization with the refresh pulse signal SRP.

The temperature selection signal generation circuit 430 generates the sixth temperature selection signal TPS6 enabled to a logic high level (H), with remaining temperature selection signals TPS1 to TPS5 and TPS7 to TPS8 disabled to a logic low level (L), when the first bit RCD<1> of the refresh code signal is at a logic high level (H), the second bit RCD<2> of the refresh code signal is at a logic high level (H), and the third bit RCD<3>of the refresh code signal is at a logic low level (L) in synchronization with the refresh pulse signal SRP.

The temperature selection signal generation circuit 430 generates the fifth temperature selection signal TPS5 enabled to a logic high level (H), with remaining temperature selection signals TPS1 to TPS4 and TPS6 to TPS8 disabled to a logic low level (L), when the first bit RCD<1> of the refresh code signal is at a logic low level (L), the second bit RCD<2> of the refresh code signal is at a logic high level (H), and the third bit RCD<3> of the refresh code signal is at a logic low level (L) in synchronization with the refresh pulse signal SRP.

The temperature selection signal generation circuit 430 generates the fourth temperature selection signal TPS4 enabled to a logic high level (H), with remaining temperature selection signals TPS1 to TPS3 and TPS5 to TPS8 disabled to a logic low level (L), when the first bit RCD<1> of the refresh code signal is at a logic low level (L), the second bit RCD<2> of the refresh code signal is at a logic high level (H), and the third bit RCD<3> of the refresh code signal is at a logic high level (H) in synchronization with the refresh pulse signal SRP.

The temperature selection signal generation circuit 430 generates the third temperature selection signal TPS3 enabled to a logic high level (H), with remaining temperature selection signals TPS1 to TPS2 and TPS4 to TPS8 disabled to a logic low level (L), when the first bit RCD<1> of the refresh code signal is at a logic high level (H), the second bit RCD<2> of the refresh code signal is at a logic high level (H), and the third bit RCD<3> of the refresh code signal is at a logic high level (H) in synchronization with the refresh pulse signal SRP.

The temperature selection signal generation circuit 430 generates the second temperature selection signal TPS2 enabled to a logic high level (H), with remaining temperature selection signals TPS1 and TPS3 to TPS8 disabled to a logic low level (L), when the first bit RCD<1> of the refresh code signal is at a logic high level (H), the second bit RCD<2> of the refresh code signal is at a logic low level (L), and the third bit RCD<3> of the refresh code signal is at a logic high level (H) in synchronization with the refresh pulse signal SRP.

The temperature selection signal generation circuit 430 generates the first temperature selection signal TPS1 enabled to a logic high level (H), with remaining temperature selection signals TPS2 to TPS8 disabled to a logic low level (L), when the first bit RCD<1> of the refresh code signal is at a logic low level (L), the second bit RCD<2> of the refresh code signal is at a logic low level (L), and the third bit RCD<3> of the refresh code signal is at a logic high level (H) in synchronization with the refresh pulse signal SRP.

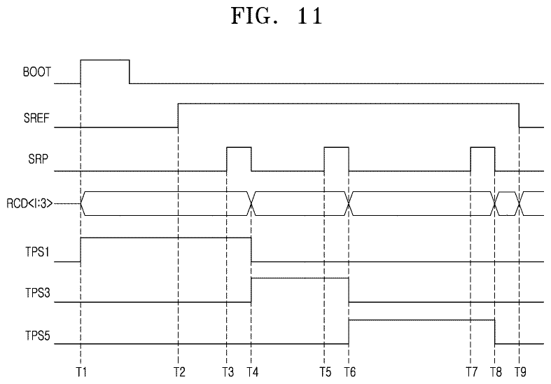

FIG. 11 is a timing diagram for describing an operation of adjusting, by the first core die 121-1, the cycle of a self-refresh operation based on a temperature interval after the start of the self-refresh operation after a boot-up operation according to an embodiment of the present disclosure.

At time T1, the command decoder 310 generates the boot-up signal BOOT that is enabled to a logic high level (H) when the first to L-th bits CMD<1:L> of the command have a combination of logic levels for performing a boot-up operation.

When the boot-up signal BOOT is enabled to a logic high level (H), the refresh code signal generation circuit 420 generates the first to third bits RCD<1:3> of the refresh code signal, which are initialized as a combination of logic levels corresponding to a high temperature. At this time, the refresh code signal generation circuit 420 generates the first bit RCD<1> of the refresh code signal at a logic low level (L), generates the second bit RCD<2> of the refresh code signal at a logic low level (L), and generates the third bit RCD<3> of the refresh code signal at a logic high level (H).

The temperature selection signal generation circuit 430 generates the first temperature selection signal TPS1 that is enabled to a logic high level based on the first to third bits RCD<1:3> of the refresh code signal, which are set as a combination of logic levels corresponding to a high temperature, when the boot-up signal BOOT is enabled.

At time T2, the command decoder 310 generates the self-refresh signal SREF that is enabled to a logic high level when the first to L-th bits CMD<1:L> of the command have a combination of logic levels for performing a self-refresh operation.

At time T3, the self-refresh control circuit 440 generates the refresh pulse signal SRP from the first division clock signal DCLK1 when the first temperature selection signal TPS1 is enabled during the interval for which the self-refresh signal SREF is enabled. That is, the self-refresh control circuit 440 generates the refresh pulse signal SRP having the fastest cycle when the self-refresh operation is entered.

At time T4, the self-refresh control circuit 440 generates the refresh pulse signal SRP that is disabled to a logic low level (L).

The refresh code signal generation circuit 420 receives the first to eighth bits TCD<1:8> of the temperature code signal during the interval in which the temperature interval is 120° C. to 149° C. in synchronization with the temperature clock signal TCLK during the interval for which the self-refresh signal SREF is enabled. The refresh code signal generation circuit 420 generates the first bit RCD<1> of the refresh code signal at a logic high level (H), generates the second bit RCD<2> of the refresh code signal at a logic high level (H), and generates the third bit RCD<3> of the refresh code signal at a logic high level (H), based on a combination of the logic levels of the first to eighth bits TCD<1:8> of the temperature code signal in synchronization with the refresh clock signal RCLK during the interval for which the self-refresh signal SREF is enabled.

The temperature selection signal generation circuit 430 generates the third temperature selection signal TPS3 that is enabled to a logic high level (H) based on the first to third bits RCD<1:3> of the refresh code signal in synchronization with the refresh pulse signal SRP.

At time T5, the self-refresh control circuit 440 generates the refresh pulse signal SRP from the third division clock signal DCLK3 when the third temperature selection signal TPS3 is enabled during the interval for which the self-refresh signal SREF is enabled. That is, the self-refresh control circuit 440 generates the refresh pulse signal SRP having a cycle corresponding to the temperature interval of 120° C. to 149° C.

At time T6, the self-refresh control circuit 440 generates the refresh pulse signal SRP that is disabled to a logic low level (L).

The refresh code signal generation circuit 420 receives the first to eighth bits TCD<1:8> of the temperature code signal during the interval in which the temperature interval is 60° C. to 89° C. in synchronization with the temperature clock signal TCLK during the interval for which the self-refresh signal SREF is enabled. The refresh code signal generation circuit 420 generates the first bit RCD<1> of the refresh code signal at a logic low level (L), generates the second bit RCD<2> of the refresh code signal at a logic high level (H), and generates the third bit RCD<3> of the refresh code signal at a logic low level (L), based on a combination of the logic levels of the first to eighth bits TCD<1:8> of the temperature code signal in synchronization with the refresh clock signal RCLK during the interval for which the self-refresh signal SREF is enabled.

The temperature selection signal generation circuit 430 generates the fifth temperature selection signal TPS5 that is enabled to a logic high level based on the first to third bits RCD<1:3> of the refresh code signal in synchronization with the refresh pulse signal SRP.

At time T7, the self-refresh control circuit 440 generates the refresh pulse signal SRP from the fifth division clock signal DCLK5 when the fifth temperature selection signal TPS5 is enabled during the interval for which the self-refresh signal SREF is enabled. That is, the self-refresh control circuit 440 generates the refresh pulse signal SRP having a cycle corresponding to the temperature interval of 60° C. to 89° C.

At time T8, the self-refresh control circuit 440 generates the refresh pulse signal SRP that is disabled to a logic low level (L).

At time T9, the command decoder 310 generates the self-refresh signal SREF that is disabled to a logic low level (H) when the first to L-th bits CMD<1:L> of the command do not have a combination of logic levels for performing a self-refresh operation.

That is, the self-refresh operation is performed and the cycle of the self-refresh operation is adjusted based on the temperature interval from time T2 to time T9.

As described above, the memory system 1, according to an embodiment of the present disclosure, can prevent an error of a self-refresh operation by adjusting the cycle of the self-refresh operation based on the refresh code signal that is set as a gray code in synchronization with the refresh clock signal that is generated within channels of the core dies. The memory system 1 can perform a self-refresh operation by adjusting the cycle of the self-refresh operation of each of a plurality of channels included in the core dies by latching the refresh code signal that is set as a gray code, within the plurality of channels.

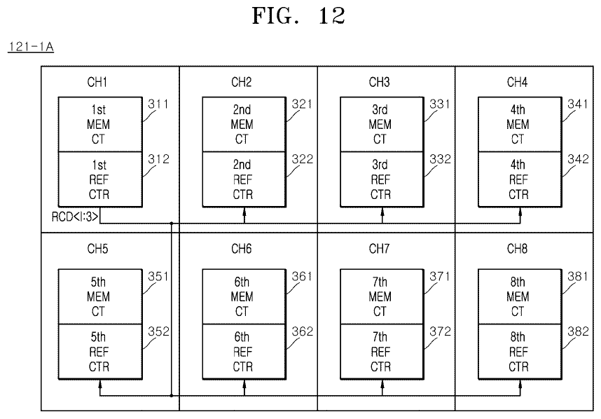

FIG. 12 is a block diagram illustrating a construction of the first core die 121-1 according to another embodiment of the present disclosure. As illustrated in FIG. 12, a first core die 121-1A may include a first channel CH1, a second channel CH2, a third channel CH3, a fourth channel CH4, a fifth channel CH5, a sixth channel CH6, a seventh channel CH7, and an eighth channel CH8.

The first channel CH1 may include a first memory circuit (1^{st} MEM CT) 311 and a first refresh control circuit (1^{st} REF CTR) 312.

The first memory circuit 311 may perform a boot-up operation, a write operation, a read operation, and a self-refresh operation based on the command CMD<1:L> (shown in FIG. 3) and the address ADD<1:M> (shown in FIG. 3). The first memory circuit 311 may perform various operations based on the command CMD<1:L> and the address ADD<1:M>. The first memory circuit 311 may output the fuse data FZD<1:K> (shown in FIG. 3) programmed in the fuse area 330 after the start of a boot-up operation based on the command CMD<1:L> and the address ADD<1:M>. The first memory circuit 311 may store the data DATA<1:J> (shown in FIG. 3) in the memory area 340 after the start of a write operation based on the command CMD<1:L> and the address ADD<1:M>. The first memory circuit 311 may output the data DATA<1:J> stored in the memory area 340 after the start of a read operation based on the command CMD<1:L> and the address ADD<1:M>. The first memory circuit 311 may perform a self-refresh operation by the refresh pulse signal SRP (shown in FIG. 4) after the start of a self-refresh operation based on the command CMD<1:L>.

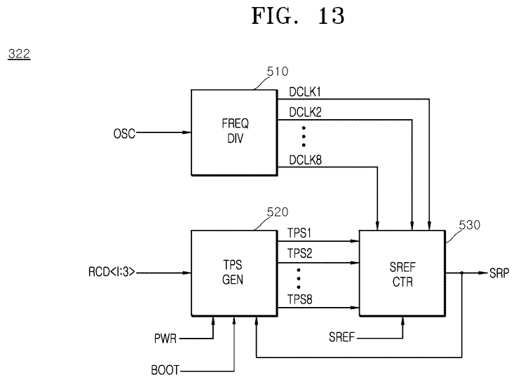

The first refresh control circuit 312 may generate the first to third bits RCD<1:3> of the refresh code signal, which are set as a gray code, based on the temperature code signal TCD<1:8> (shown in FIG. 4). The first refresh control circuit 312 may generate the refresh pulse signal SRP (shown in FIG. 13) having a generation cycle adjusted based on a combination of the logic levels of the first to third bits RCD<1:3> of the refresh code signal. The first refresh control circuit 312 may adjust the generation cycle of the refresh pulse signal SRP by latching the first to third bits RCD<1:3> of the refresh code signal in synchronization with the refresh pulse signal SRP).

The first refresh control circuit 312 is implemented with the same components as the first refresh control circuit 212 illustrated in FIG. 4 and performs the same operation as the first refresh control circuit 212, and thus, a detailed description thereof is not repeated.

The second channel CH2 may include a second memory circuit (2^{nd} MEM CT) 321 and a second refresh control circuit (2^{nd} REF CTR) 322.

The second memory circuit 321 includes the same components as the first memory circuit 311 and performs the same operation as the first memory circuit 311, and thus, a detailed description thereof is not repeated.

The second refresh control circuit 322 may receive the first to third bits RCD<1:3> of a refresh code signal from the first refresh control circuit 312. The second refresh control circuit 322 may generate the refresh pulse signal SRP (shown in FIG. 13) having a generation cycle adjusted based on a combination of the logic levels of the first to third bits RCD<1:3> of the refresh code signal. The second refresh control circuit 322 may adjust the generation cycle of the refresh pulse signal SRP by latching the first to third bits RCD<1:3> of the refresh code signal in synchronization with the refresh pulse signal SRP.

The third channel CH3 may include a third memory circuit (3^{rd} MEM CT) 331 and a third refresh control circuit (3^{rd} REF CTR) 332. The fourth channel CH4 may include a fourth memory circuit (4^{th} MEM CT) 341 and a fourth refresh control circuit (4^{th} REF CTR) 342. The fifth channel CH5 may include a fifth memory circuit (5^{th} MEM CT) 351 and a fifth refresh control circuit (5^{th} REF CTR) 352. The sixth channel CH6 may include a sixth memory circuit (6^{th} MEM CT) 361 and a sixth refresh control circuit (6^{th} REF CTR) 362. The seventh channel CH7 may include a seventh memory circuit (7^{th} MEM CT) 371 and a seventh refresh control circuit (7^{th} REF CTR) 372. The eighth channel CH8 may include an eighth memory circuit (8^{th} MEM CT) 381 and an eighth refresh control circuit (8^{th} REF CTR) 382.

Each of the second to eighth memory circuits 321 to 381 included in the second to eighth channels CH2 to CH8, respectively, includes the same components as the first memory circuit 311 and performs the same operation as the first memory circuit 311, and thus, a detailed description thereof is not repeated.

Each of the second to eighth refresh control circuits 322 to 382 included in the second to eighth channels CH2 to CH8 may receive the first to third bits RCD<1:3> of the refresh code signal from the first refresh control circuit 312, and may adjust the generation cycle of the refresh pulse signal (SRP in FIG. 13).

FIG. 13 is a block diagram illustrating a construction of the second refresh control circuit 322 according to another embodiment of the present disclosure. As illustrated in FIG. 13, the second refresh control circuit 322 may include a frequency division circuit (FREQ DIV) 510, a temperature selection signal generation circuit (TPS GEN) 520, and a self-refresh control circuit (SREF CTR) 530.

The frequency division circuit 510 may generate a refresh clock signal RCLK based on a cycle signal OSC. The frequency division circuit 510 may generate the refresh clock signal RCLK having the same generation cycle as the cycle signal OSC. The cycle signal OSC may be a signal including a pulse that is periodically generated.

The frequency division circuit 510 may generate first to eighth division clock signals DCLK1 to DCLK8 based on the cycle signal OSC. The frequency division circuit 510 may generate the first to eighth division clock signals DCLK1 to DCLK8 having generation cycles sequentially increased by dividing the frequency of the cycle signal OSC. The frequency division circuit 510 may generate the first division clock signal DCLK1 having the same generation cycle as the cycle signal OSC. The frequency division circuit 510 may generate the second division clock signal DCLK2 having a generation cycle that is twice the generation cycle of the cycle signal OSC. The frequency division circuit 510 may generate the third division clock signal DCLK3 having a generation cycle that is three times the generation cycle of the cycle signal OSC. The frequency division circuit 510 may generate the fourth division clock signal DCLK4 having a generation cycle that is four times the generation cycle of the cycle signal OSC. The frequency division circuit 510 may generate the fifth division clock signal DCLK5 having a generation cycle that is five times the generation cycle of the cycle signal OSC. The frequency division circuit 510 may generate the sixth division clock signal DCLK6 having a generation cycle that is six times the generation cycle of the cycle signal OSC. The frequency division circuit 510 may generate the seventh division clock signal DCLK7 having a generation cycle that is seven times the generation cycle of the cycle signal OSC. The frequency division circuit 510 may generate the eighth division clock signal DCLK8 having a generation cycle that is eight times the generation cycle of the cycle signal OSC. An operation of generating, by the frequency division circuit 510, the second division clock signal DCLK2 having a generation cycle that is twice the generation cycle of the cycle signal OSC may be an operation of generating the second division clock signal DCLK2 including a pulse that is generated in a frequency that is half the generation cycle of a pulse included in the cycle signal OSC.

The first to eighth division clock signals DCLK1 to DCLK8 may each be generated to have a different generation cycle. The first division clock signal DCLK1 may be generated including a pulse having a cycle of 0.5 μs, that is, a first cycle. The second division clock signal DCLK2 may be generated including a pulse having a cycle of 1 μs, that is, a second cycle. The third division clock signal DCLK3 may be generated including a pulse having a cycle of 2 μs, that is, a third cycle. The fourth division clock signal DCLK4 may be generated including a pulse having a cycle of 4 μs, that is, a fourth cycle. The fifth division clock signal DCLK5 may be generated including a pulse having a cycle of 8 μs, that is, a fifth cycle. The sixth division clock signal DCLK6 may be generated including a pulse having a cycle of 16 μs, that is, a sixth cycle. The seventh division clock signal DCLK7 may be generated including a pulse having a cycle of 32 μs, that is, a seventh cycle. The eighth division clock signal DCLK8 may be generated including a pulse having a cycle of 64 μs, that is, an eighth cycle. The abbreviation “μs” for microsecond indicates 10⁻⁶ second.

The temperature selection signal generation circuit 520 may generate first to eighth temperature selection signals TPS1 to TPS8, all of which are disabled when a power-up signal PWR is enabled. The temperature selection signal generation circuit 520 may generate the first temperature selection signal TPS1 that is enabled based on the first to third bits RCD<1:3> of the refresh code signal, which are set as a combination of logic levels corresponding to a high temperature, when a boot-up signal BOOT is enabled. The temperature selection signal generation circuit 520 may generate the first to eighth temperature selection signals TPS1 to TPS8 based on the first to third bits RCD<1:3> of the refresh code signal in synchronization with the refresh pulse signal SRP. The temperature selection signal generation circuit 520 may generate the first to eighth temperature selection signals TPS1 to TPS8 that are selectively enabled by decoding the first to third bits RCD<1:3> of the refresh code signal when the level of the refresh pulse signal SRP transitions to a logic low level.

The self-refresh control circuit 530 may generate the refresh pulse signal SRP having a generation cycle adjusted, based on the first to eighth temperature selection signals TPS1 to TPS8 and the first to eighth division clock signals DCLK1 to DCLK8 during an interval for which a self-refresh signal SREF is enabled. The self-refresh control circuit 530 may generate the refresh pulse signal SRP from the first division clock signal DCLK1 when the first temperature selection signal TPS1 is enabled during the interval for which the self-refresh signal SREF is enabled. The self-refresh control circuit 530 may generate the refresh pulse signal SRP from the second division clock signal DCLK2 when the second temperature selection signal TPS2 is enabled during the interval for which the self-refresh signal SREF is enabled. The self-refresh control circuit 530 may generate the refresh pulse signal SRP from the third division clock signal DCLK3 when the third temperature selection signal TPS3 is enabled during the interval for which the self-refresh signal SREF is enabled. The self-refresh control circuit 530 may generate the refresh pulse signal SRP from the fourth division clock signal DCLK4 when the fourth temperature selection signal TPS4 is enabled during the interval for which the self-refresh signal SREF is enabled. The self-refresh control circuit 530 may generate the refresh pulse signal SRP from the fifth division clock signal DCLK5 when the fifth temperature selection signal TPS5 is enabled during the interval for which the self-refresh signal SREF is enabled. The self-refresh control circuit 530 may generate the refresh pulse signal SRP from the sixth division clock signal DCLK6 when the sixth temperature selection signal TPS6 is enabled during the interval for which the self-refresh signal SREF is enabled. The self-refresh control circuit 530 may generate the refresh pulse signal SRP from the seventh division clock signal DCLK7 when the seventh temperature selection signal TPS7 is enabled during the interval for which the self-refresh signal SREF is enabled. The self-refresh control circuit 530 may generate the refresh pulse signal SRP from the eighth division clock signal DCLK8 when the eighth temperature selection signal TPS8 is enabled during the interval for which the self-refresh signal SREF is enabled.

Each of the third to eighth refresh control circuits 321 to 381 included in the third to eighth channels CH3 to CH8, respectively, include the same components as the second refresh control circuit 322 illustrated in FIG. 3 and performs the same operation as the second refresh control circuit 322, and thus, a detailed description thereof is not repeated.

As described above, the memory system 1, according to an embodiment of the present disclosure, can prevent an error of a self-refresh operation by adjusting the cycle of the self-refresh operation based on the refresh code signal that is set as a gray code in synchronization with the refresh clock signal that is generated within the channels of the core dies. The memory system 1 can perform a self-refresh operation by adjusting the cycle of the self-refresh operation of each of a plurality of channels included in the core dies by latching the refresh code signal that is set as a gray code, within the plurality of channels.

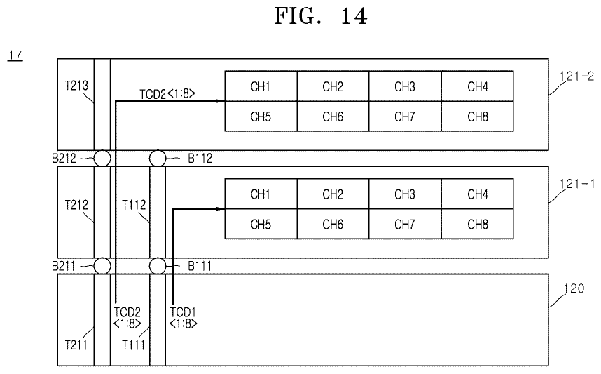

FIG. 14 is a diagram for describing an operation of the memory device 17 according to an embodiment of the present disclosure. A self-refresh operation of the memory device 17 is described with reference to FIG. 14. In this case, self-refresh operations of a base die 120, a first core die 121-1, and a second core die 121-2 are described as an example as follows.

The base die 120 may include a first TSV T111 and a second TSV T211. The first TSV T111 may be electrically connected to a first micro bump pad B111. The second TSV T211 may be electrically connected to a second micro bump pad B211.

The base die 120 may output first to eighth bits TCD1<1:8> of a first temperature code signal to the first core die 121-1 through the first TSV T111 and the first micro bump pad B111. The base die 120 may output first to eighth bits TCD2<1:8> of a second temperature code signal to the second core die 121-2 through the second TSV T211 and the second micro bump pad B211.

The first core die 121-1 may be vertically stacked over the base die 120 through the first micro bump pad B111 and the second micro bump pad B211. The first core die 121-1 may include a third TSV T112 and a fourth TSV T212. The third TSV T112 may be electrically connected to the first micro bump pad B111 and a third micro bump pad B112. The fourth TSV T212 may be electrically connected to the second micro bump pad B211 and the fourth micro bump pad B212.

The first core die 121-1 may include a first channel CH1, a second channel CH2, a third channel CH3, a fourth channel CH4, a fifth channel CH5, a sixth channel CH6, a seventh channel CH7, and an eighth channel CH8.

The first channel CH1, second channel CH2, third channel CH3, fourth channel CH4, fifth channel CH5, sixth channel CH6, seventh channel CH7, and eighth channel CH8 of the first core die 121-1 may receive the first to eighth bits TCD1<1:8> of the first temperature code signal through the third TSV T112. The first channel CH1, second channel CH2, third channel CH3, fourth channel CH4, fifth channel CH5, sixth channel CH6, seventh channel CH7, and eighth channel CH8 of the first core die 121-1 may each adjust the cycle of a self-refresh operation based on the refresh code signal RCD<1:3>, that is, a gray code, in synchronization with the refresh clock signal RCLK that is generated within each channel by receiving the first to eighth bits TCD1<1:8> of the first temperature code signal.

Each of the first channel CH1, second channel CH2, third channel CH3, fourth channel CH4, fifth channel CH5, sixth channel CH6, seventh channel CH7, and eighth channel CH8 of the first core die 121-1 is implemented identically with each of the first channel CH1, the second channel CH2, the third channel CH3, the fourth channel CH4, the fifth channel CH5, the sixth channel CH6, the seventh channel CH7, and the eighth channel CH8 illustrated in FIGS. 2 and 12, and operates identically with each of the first channel CH1, the second channel CH2, the third channel CH3, the fourth channel CH4, the fifth channel CH5, the sixth channel CH6, the seventh channel CH7, and the eighth channel CH8 illustrated in FIGS. 2 and 12, and thus, a detailed description thereof is not repeated.

The second core die 121-2 may be vertically stacked over the first core die 121-2 through a third micro bump pad B112 and a fourth micro bump pad B212. The second core die 121-2 may include a fifth TSV T213. The fifth TSV T213 may be electrically connected to the fourth micro bump pad B212. The fourth TSV T212 may be electrically connected to the second micro bump pad B211 and the fourth micro bump pad B212.

The second core die 121-2 may include a first channel CH1, a second channel CH2, a third channel CH3, a fourth channel CH4, a fifth channel CH5, a sixth channel CH6, a seventh channel CH7, and an eighth channel CH8.

The first channel CH1, second channel CH2, third channel CH3, fourth channel CH4, fifth channel CH5, sixth channel CH6, seventh channel CH7, and eighth channel CH8 of the second core die 121-2 may receive the first to eighth bits TCD2<1:8> of the second temperature code signal through the fifth TSV T213. The first channel CH1, second channel CH2, third channel CH3, fourth channel CH4, fifth channel CH5, sixth channel CH6, seventh channel CH7, and eighth channel CH8 of the second core die 121-2 may each adjust the cycle of a self-refresh operation based on the refresh code signal RCD<1:3>, that is, a gray code, in synchronization with the refresh clock signal RCLK that is generated within each channel by receiving the first to eighth bits TCD2<1:8> of the second temperature code signal.

Each of the first channel CH1, second channel CH2, third channel CH3, fourth channel CH4, fifth channel CH5, sixth channel CH6, seventh channel CH7, and eighth channel CH8 of the second core die 121-2 is implemented identically with each of the first channel CH1, the second channel CH2, the third channel CH3, the fourth channel CH4, the fifth channel CH5, the sixth channel CH6, the seventh channel CH7, and the eighth channel CH8 illustrated in FIGS. 2 and 12 and operates identically with each of the first channel CH1, the second channel CH2, the third channel CH3, the fourth channel CH4, the fifth channel CH5, the sixth channel CH6, the seventh channel CH7, and the eighth channel CH8 illustrated in FIGS. 2 and 12, and thus, a detailed description thereof is not repeated.

As described above, the memory system 1 according to an embodiment of the present disclosure can prevent an error of a self-refresh operation by adjusting the cycle of the self-refresh operation based on the refresh code signal that is as a gray code in synchronization with the refresh clock signal that is generated within the channels of the core dies. The memory system 1 can perform a self-refresh operation by adjusting the cycle of the self-refresh operation of each of a plurality of channels included in the core dies by latching the refresh code signal that is set as a gray code within the plurality of channels.

What is claimed is:

1. A memory device comprising:
a base die configured to output a temperature code signal after a start of a self-refresh operation; and
a core die configured to generate a refresh code signal that is set as a gray code based on the temperature code signal, configured to perform the self-refresh operation based on a refresh pulse signal having a generation cycle adjusted based on a combination of logic levels of the refresh code signal, and configured to adjust the generation cycle of the refresh pulse signal by latching the refresh code signal in synchronization with the refresh pulse signal.

2. The memory device of claim 1, wherein:
the refresh code signal comprises a plurality of bits, and
a logic level of any one of the plurality of bits included in the refresh code signal is changed when a combination of logic levels of the temperature code signal is changed.

3. The memory device of claim 1, wherein the refresh code signal is initialized as a combination of logic levels corresponding to a high temperature after a start of a boot-up operation.

4. The memory device of claim 1, wherein the core die comprises:
a memory circuit configured to perform the self-refresh operation based on the refresh pulse signal; and
a refresh control circuit configured to generate the refresh code signal based on the temperature code signal, configured to generate the refresh pulse signal based on a combination of the logic levels of the refresh code signal, and configured to adjust the generation cycle of the refresh pulse signal by latching the refresh code signal in synchronization with the refresh pulse signal.

5. The memory device of claim 4, wherein the refresh control circuit comprises:
a frequency division circuit configured to generate a plurality of division clock signals by dividing a frequency of a cycle signal and configured to generate a refresh clock signal;
a refresh code signal generation circuit configured to receive the temperature code signal in synchronization with a temperature clock signal during an interval for which a self-refresh signal is enabled and configured to generate the refresh code signal, which is initialized as a combination of logic levels corresponding to a high temperature when a boot-up signal is enabled, based on a combination of logic levels of the temperature code signal in synchronization with the refresh clock signal;
a temperature selection signal generation circuit configured to generate a plurality of temperature selection signals all of which are disabled when a power-up signal is enabled by decoding the refresh code signal in synchronization with the refresh pulse signal; and
a self-refresh control circuit configured to generate the refresh pulse signal having the generation cycle adjusted, based on the plurality of temperature selection signals and the plurality of division clock signals during an interval for which the self-refresh signal is enabled.

6. The memory device of claim 5, wherein the self-refresh control circuit comprises:
a synthesis signal generation circuit configured to generate a synthesis signal by synthesizing the plurality of temperature selection signals and the plurality of division clock signals; and
a refresh pulse signal generation circuit configured to generate the refresh pulse signal by delaying the synthesis signal during the interval for which the self-refresh signal is enabled.

7. The memory device of claim 6, wherein the synthesis signal generation circuit comprises:
a selection clock signal generation circuit configured to output the plurality of division clock signals corresponding to a signal that is enabled, among the plurality of temperature selection signals, as a plurality of selection clock signals; and
a first logic circuit configured to generate the synthesis signal by synthesizing the plurality of selection clock signals.

8. The memory device of claim 6, wherein the refresh pulse signal generation circuit comprises:
a delay circuit configured to generate a delayed synthesis signal by delaying the synthesis signal; and
a second logic circuit configured to output the delayed synthesis signal as the refresh pulse signal during the interval for which the self-refresh signal is enabled.

9. A memory device comprising:
a base die configured to output a temperature code signal after a start of a self-refresh operation; and
a core die comprising first and second channels,
wherein the first channel is configured to generate a first refresh code signal that is set as a gray code based on the temperature code signal, perform the self-refresh operation based on a first refresh pulse signal having a generation cycle adjusted based on a combination of logic levels of the first refresh code signal, and adjust the generation cycle of the first refresh pulse signal by latching the first refresh code signal in synchronization with the first refresh pulse signal, and
wherein the second channel is configured to generate a second refresh code signal that is set as a gray code based on the temperature code signal, perform the self-refresh operation based on a second refresh pulse signal having a generation cycle adjusted based on a combination of logic levels of the second refresh code signal, and adjust the generation cycle of the second refresh pulse signal by latching the second refresh code signal in synchronization with the second refresh pulse signal.

10. The memory device of claim 9, wherein:
the first refresh code signal comprises a plurality of bits, and a logic level of any one of the plurality of bits included in the first refresh code signal is changed when a combination of logic levels of the temperature code signal is changed, and
the second refresh code signal comprises a plurality of bits, and a logic level of any one of the plurality of bits included in the second refresh code signal is changed when a combination of logic levels of the temperature code signal is changed.

11. The memory device of claim 9, wherein each of the first and second refresh code signals is initialized as a combination of logic levels corresponding to a high temperature after a start of a boot-up operation.

12. The memory device of claim 9, wherein the first channel comprises:
a first memory circuit configured to perform the self-refresh operation based on the first refresh pulse signal; and
a first refresh control circuit configured to generate the first refresh code signal based on the temperature code signal, configured to generate the first refresh pulse signal based on a combination of the logic levels of the first refresh code signal, and configured to adjust the generation cycle of the first refresh pulse signal by latching the first refresh code signal in synchronization with the first refresh pulse signal.

13. The memory device of claim 12, wherein the first refresh control circuit comprises:
a first frequency division circuit configured to generate a plurality of division clock signals by dividing a frequency of a cycle signal and configured to generate a refresh clock signal;
a first refresh code signal generation circuit configured to receive the temperature code signal in synchronization with a temperature clock signal during an interval for which a self-refresh signal is enabled and configured to generate the first refresh code signal, which is initialized as a combination of logic levels corresponding to a high temperature when a boot-up signal is enabled, based on a combination of logic levels of the temperature code signal in synchronization with the refresh clock signal;
a first temperature selection signal generation circuit configured to generate a plurality of temperature selection signals all of which are disabled when a power-up signal is enabled by decoding the first refresh code signal in synchronization with the first refresh pulse signal; and
a first self-refresh control circuit configured to generate the first refresh pulse signal having the generation cycle adjusted, based on the plurality of temperature selection signals and the plurality of division clock signals during an interval for which the self-refresh signal is enabled.

14. The memory device of claim 13, wherein the first self-refresh control circuit comprises:
a first synthesis signal generation circuit configured to generate a first synthesis signal by synthesizing the plurality of temperature selection signals and the plurality of division clock signals; and
a first refresh pulse signal generation circuit configured to generate the first refresh pulse signal by delaying the first synthesis signal during the interval for which the self-refresh signal is enabled.

15. The memory device of claim 9, wherein the second channel comprises:
a second memory circuit configured to perform the self-refresh operation based on the second refresh pulse signal; and
a second refresh control circuit configured to generate the second refresh code signal based on the temperature code signal, configured to generate the second refresh pulse signal based on a combination of the logic levels of the second refresh code signal, and configured to adjust the generation cycle of the second refresh pulse signal by latching the second refresh code signal in synchronization with the second refresh pulse signal.

16. The memory device of claim 15, wherein the second refresh control circuit comprises:
a second frequency division circuit configured to generate a plurality of division clock signals by dividing a frequency of a cycle signal and configured to generate a refresh clock signal;
a second refresh code signal generation circuit configured to receive the temperature code signal in synchronization with a temperature clock signal during an interval for which a self-refresh signal is enabled and configured to generate the second refresh code signal, which is initialized as a combination of logic levels corresponding to a high temperature when a boot-up signal is enabled, based on a combination of logic levels of the temperature code signal in synchronization with the refresh clock signal;
a second temperature selection signal generation circuit configured to generate a plurality of temperature selection signals all of which are disabled when a power-up signal is enabled by decoding the second refresh code signal in synchronization with the second refresh pulse signal; and
a second self-refresh control circuit configured to generate the second refresh pulse signal having the generation cycle adjusted, based on the plurality of temperature selection signals and the plurality of division clock signals during an interval for which the self-refresh signal is enabled.

17. The memory device of claim 16, wherein the second self-refresh control circuit comprises:
a second synthesis signal generation circuit configured to generate a second synthesis signal by synthesizing the plurality of temperature selection signals and the plurality of division clock signals; and
a second refresh pulse signal generation circuit configured to generate the second refresh pulse signal by delaying the second synthesis signal during the interval for which the self-refresh signal is enabled.

18. A memory device comprising:
a base die configured to output a temperature code signal after a start of a self-refresh operation; and
a core die comprising first and second channels,
wherein the first channel is configured to generate a refresh code signal that is set as a gray code based on the temperature code signal, perform the self-refresh operation based on a first refresh pulse signal having a generation cycle adjusted based on a combination of logic levels of the refresh code signal, and adjust the generation cycle of the first refresh pulse signal by latching the refresh code signal in synchronization with the first refresh pulse signal, and
wherein the second channel is configured to receive the refresh code signal from the first channel, perform the self-refresh operation based on a second refresh pulse signal having a generation cycle adjusted based on a combination of logic levels of the refresh code signal, and adjust the generation cycle of the second refresh pulse signal by latching the refresh code signal in synchronization with the second refresh pulse signal.

19. The memory device of claim 18, wherein:
the refresh code signal comprises a plurality of bits, and
a logic level of any one of the plurality of bits included in the refresh code signal is changed when a combination of logic levels of the temperature code signal is changed.

20. The memory device of claim 18, wherein the refresh code signal is initialized as a combination of logic levels corresponding to a high temperature after a start of a boot-up operation.

21. The memory device of claim 18, wherein the first channel comprises:
a first memory circuit configured to perform the self-refresh operation based on the first refresh pulse signal; and
a first refresh control circuit configured to generate the refresh code signal based on the temperature code signal, configured to generate the first refresh pulse signal based on a combination of the logic levels of the refresh code signal, and configured to adjust the generation cycle of the first refresh pulse signal by latching the refresh code signal in synchronization with the first refresh pulse signal.

22. The memory device of claim 18, wherein the second channel comprises:
a second memory circuit configured to perform the self-refresh operation based on the second refresh pulse signal; and
a second refresh control circuit configured to receive the refresh code signal, configured to generate the second refresh pulse signal based on a combination of the logic levels of the refresh code signal, and configured to adjust the generation cycle of the second refresh pulse signal by latching the refresh code signal in synchronization with the second refresh pulse signal.
